(19) United States
(12) Patent Application Publication
(10) Pub. No.: US 2026/0358380 A1
(43) Pub. Date: Nov. 12, 2026

(54) CURRENT SENSOR

(71) Applicant: Asahi Kasei Microdevices Corporation, Tokyo (JP)

(72) Inventors: Keito KOBAYASHI, Tokyo (JP); Masato INOUE, Tokyo (JP)

(21) Appl. No.: 19/660,134

(22) Filed: Apr. 27, 2026

(30) Foreign Application Priority Data
May 7, 2025 (JP) 2025-077533
Apr. 1, 2026 (JP) 2026-060409

(51) Int. Cl. G01R 15/20; G01R 19/00

(52) U.S. Cl. CPC G01R 15/205; G01R 19/0092

(57) ABSTRACT

A current sensor includes a conductor and a magnetoelectric conversion element, and the conductor has a first and second terminal portions, a turn portion, and first and second body portions. The first body portion has a first flow path portion and a first enlarged portion. The second body portion has a second flow path portion and a second enlarged portion. The magnetoelectric conversion element is located between the first and second flow path portions at a position overlapping a center line that is equidistant from a side of the first flow path portion and a side of the second flow path portion. Distances from a centroid of the magnetoelectric conversion element to the side of the first flow path portion and to the side of the second flow path portion are smaller than a distance from the centroid of the magnetoelectric conversion element to a side of the turn portion.

### CROSS-REFERENCE TO RELATED APPLICATION

The contents of the following patent application(s) are incorporated herein by reference:

NO. 2025-077533 filed in JP on May 7, 2025

NO. 2026-060409 filed in JP on Apr. 1, 2026

### BACKGROUND

### 1. Technical Field

The present invention relates to a current sensor.

### 2. Related Art

Patent Document 1 discloses a current sensor including the conductor, the magnetoelectric conversion element arranged in the vicinity of the conductor, and the insulating member supporting the magnetoelectric conversion element, the current sensor being arranged such that the conductor does not contact the insulating member and does not support the insulating member. Patent Document 2 discloses a current sensor in which, in a plan view, the magnetic field sensor is arranged so as to overlap an edge of the conductor.

### Related Art Documents

### Patent Documents

Patent Document 1: U.S. Patent No. 10,101,368 Specification

Patent Document 2: U.S. Patent No. 9,529,013 Specification

### BRIEF DESCRIPTION OF THE DRAWINGS

FIG. 1 is the schematic configuration diagram of the magnetoresistive element having an annular structure.

FIG. 2 is a diagram illustrating, when a magnetic field is input in a state inclined by 30 degrees with respect to a direction perpendicular (z-axis direction) to a magnetoresistive element having an annular structure, a state of changes, with respect to a change in a magnitude of the magnetic field, in a magnitude of magnetization in a lateral direction (x-axis direction) of magnetization of a free layer and a magnitude of magnetization in a longitudinal direction (z-axis direction) of magnetization of the free layer.

FIG. 3 is a schematic plan view of the current sensor according to a first embodiment as viewed from a ceiling surface side (z-axis direction).

FIG. 4 is a schematic plan view of the current sensor according to a second embodiment as viewed from the ceiling surface side (z-axis direction).

FIG. 5 is a plan view of the conductor included in the current sensor according to the first embodiment and the second embodiment.

FIG. 6 is a perspective view illustrating a positional relationship between the conductor used in simulation and a magnetoelectric conversion element.

FIG. 7 is a plan view of the conductor used in simulation and a magnetoelectric conversion element.

FIG. 8 is a side view of the conductor used in simulation and a magnetoelectric conversion element as viewed from an x-axis direction.

FIG. 9 is a diagram for describing the tilt angle θ used in simulation.

FIG. 10 is a diagram schematically illustrating a state of a current flowing through the conductor.

FIG. 11 is a diagram illustrating, as a result of simulation, a relationship between the y-axis-direction length l1 of a second flow path portion (a first flow path portion) and the tilt angle θ.

FIG. 12 is a diagram schematically illustrating a state of the current flowing through the conductor.

FIG. 13 is a diagram schematically illustrating a state of the current flowing through the conductor.

FIG. 14 is a diagram illustrating, as a result of simulation, a relationship between the distance wspace and the tilt angle θ when each of a low-frequency current and a high-frequency current is caused to flow through the conductor.

FIG. 15 is a diagram illustrating, as a result of simulation, a relationship between the distance wspace and a magnitude of the magnetic field detected by the magnetoelectric conversion element.

FIG. 16 is a diagram illustrating, as a result of simulation, a relationship between the y-axis-direction width l2 of the turn portion and the tilt angle θ.

FIG. 17 is a diagram illustrating the shape of a conductor used in simulation.

FIG. 18 is a diagram illustrating, as a result of simulation, a relationship between the z-axis-direction thickness t of the turn portion and the tilt angle θ.

FIG. 19 is a diagram illustrating, as a result of simulation, a relationship between the z-axis-direction thickness t of the turn portion and the magnitude of the magnetic field detected by the magnetoelectric conversion element.

FIG. 20 is a diagram illustrating an example of a positional relationship between the magnetoelectric conversion element and the conductor.

FIG. 21 is a diagram illustrating an example of a positional relationship between the magnetoelectric conversion element and the conductor.

FIG. 22 is an enlarged view of a peripheral portion including the magnetoelectric conversion element of the current sensor according to the second embodiment illustrated in FIG. 4.

FIG. 23 is a side view of the magnetoelectric conversion element and a signal processing IC.

FIG. 24A is a diagram illustrating an example of the shape of a magnetic flux loop.

FIG. 24B is a diagram illustrating an example of the shape of the magnetic flux loop.

FIG. 24C is a diagram illustrating an example of the shape of the magnetic flux loop.

FIG. 25 is a diagram for describing parasitic capacitance formed between a wire and the conductor.

FIG. 26 is a diagram schematically illustrating a state in which the magnetoelectric conversion element and the signal processing IC are electrically connected via a TSV.

FIG. 27 is a diagram schematically illustrating a state in which the magnetoelectric conversion element and the signal processing IC are electrically connected via a bump.

FIG. 28 is a diagram for describing parasitic capacitance in a case where the substrate potential of a signal processing IC is connected to a ground.

FIG. 29 is a diagram illustrating an example of a cross section of the signal processing IC.

FIG. 30 is a diagram schematically illustrating a positional relationship between the n-type deep well that is an impurity region and a wire.

FIG. 31 is a diagram illustrating an example of the structure of a magnetoresistive element.

FIG. 32 is a diagram illustrating a relationship between a magnitude of the magnetic field and a magnetoresistance change ΔR in a case where an incident magnetic field is a longitudinal magnetic field, and a relationship between a magnitude of the magnetic field and a magnetoresistance change ΔR in a case where an incident magnetic field is a transverse magnetic field, in a case where a direction of magnetization of a free layer is longitudinal and a direction of magnetization of a reference layer is longitudinal.

FIG. 33 is a diagram illustrating a relationship between the magnitude of the magnetic field and the magnetoresistance change ΔR in a case where an incident magnetic field is a longitudinal magnetic field, and a relationship between the magnitude of the magnetic field and the magnetoresistance change ΔR in a case where an incident magnetic field is a transverse magnetic field, in a case where the direction of magnetization of the free layer is transverse and the direction of magnetization of the reference layer is longitudinal.

### DESCRIPTION OF EXEMPLARY EMBODIMENTS

The following embodiments do not limit the invention according to the claims. In addition, not all of the combinations of features described in the embodiments are essential to the solving means of the invention.

A current sensor is known in which the longitudinal magnetic field type magnetic sensor that detects a longitudinal magnetic field input in a direction perpendicular to a magnetic sensing surface is arranged in the vicinity of a conductor through which a measurement current flows.

When magnetic field components of an x-axis direction and a y-axis direction, or the like along the magnetic sensing surface exist, in addition to a magnetic field component in a z-axis direction orthogonal to the magnetic sensing surface, in a magnetic field in which such a longitudinal magnetic field type magnetic sensor is present, there is a possibility that magnetic field detection accuracy decreases.

For example, the Hall element has main sensitivity to a magnetic field in a direction perpendicular to the magnetic sensing surface (z-axis direction), but also has sensitivity to a magnetic field in a horizontal direction (x-axis and y-axis directions) to the magnetic sensing surface. That is, in the Hall element, a planar Hall effect is generated by magnetic fields in the x-axis direction and the y-axis direction. Due to generation of such a planar Hall effect, there is a possibility that sensitivity of the Hall element fluctuates. As a result, there is a possibility that magnetic field detection accuracy of the Hall element decreases.

In the case of a tunnel magnetoresistive (TMR) element or a giant magnetoresistive (GMR) element, magnetization of a free layer changes due to magnetic fields in the x-axis direction and the y-axis direction, and there is a possibility that sensitivity in the z-axis direction fluctuates. When magnetization of the free layer changes in accordance with the magnetic field (main-axis magnetic field) in a direction to be detected, if the magnetic field (other-axis magnetic field) in a direction not to be detected is applied, the free layer is pseudo-magnetically biased in an other-axis direction, and thus main-axis direction sensitivity decreases. As a result, there is a possibility that the magnetic field detection accuracy of the TMR element or the GMR element decreases.

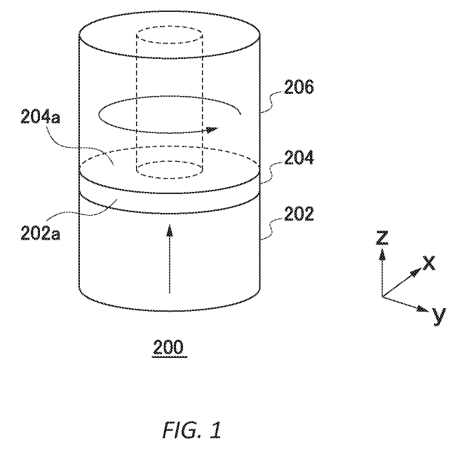

FIG. 1 is the schematic configuration diagram illustrating a magnetoresistive element 200 having an annular structure. The magnetoresistive element 200 is an example of the longitudinal magnetic field type magnetic sensor. The magnetoresistive element 200 is the vortex-type magnetoresistive element having an annular structure. The magnetoresistive element 200 includes the reference layer 202, the insulating layer 204, and the free layer 206. The reference layer 202, the insulating layer 204, and the free layer 206 may have the cylindrical structure extending in a stacking direction. The insulating layer 204 is arranged above the surface 202a of the reference layer 202, and the free layer 206 is arranged above the surface 204a of the insulating layer 204 on an opposite side from the surface facing the reference layer 202. The stacking direction of the reference layer 202, the insulating layer 204, and the free layer 206 is the z-axis direction, and directions that are along in-plane directions of the reference layer 202, the insulating layer 204, and the free layer 206, intersect the z-axis direction, and intersect each other are the x-axis direction and the y-axis direction.

The reference layer 202 is the layer, also called a fixed layer, in which a magnetization direction is fixed. The magnetization direction of the reference layer 202 exists in the stacking direction. The magnetization direction of the reference layer 202 exists in the direction intersecting the layer. The reference layer 202 may be the perpendicular magnetization film. The magnetization direction of the reference layer 202 is invariable. The invariable magnetization direction means that the magnetization direction of the reference layer 202 does not change under influence of the external magnetic field.

The reference layer 202 may be composed of, for example, at least one of tantalum (Ta), ruthenium (Ru), platinum (Pt), manganese (Mn), iridium (Ir), magnesium (Mg), copper (Cu), iron (Fe), nickel (Ni), chromium (Cr), cobalt (Co), or aluminum (Al), or an alloy thereof, more specifically platinum manganese (PtMn) or iridium manganese (IrMn). The reference layer 12 may be composed of, for example, a metal selected from the group consisting of chromium (Cr), manganese (Mn), cobalt (Co), iron (Fe), and nickel (Ni), and an alloy including one or more of these metals and exhibiting ferromagnetism. The reference layer 12 may be composed of an alloy including these metals and at least one element of boron (B), carbon (C), or nitrogen (N). The alloy may be CoFe or CoFeB, for example.

The insulating layer 204 is the layer composed of an insulator also called a tunnel layer. The free layer 206 is composed of the annular structure extending in the stacking direction. The insulating layer 14 may be composed of Al₂O₃, SiO₂, MgO, or MgAl₂O₄. The insulating layer 14 may include at least magnesium oxide (MgO).

The magnetization direction of the free layer 206 is present in the direction intersecting the stacking direction. The magnetization direction of the free layer 206 is present in the in-plane direction parallel to the layer. The magnetization direction of the free layer 206 may be set as the coreless vortex structure that, in the zero magnetic field state, is present along an in-plane direction along the layer and in a clockwise direction or a counterclockwise direction about a central axis of the annular structure.

The free layer 206 is the magnetic film that changes a direction of magnetization by an external magnetic field. The free layer 206 may be composed of, for example, at least one of tantalum (Ta), ruthenium (Ru), platinum (Pt), manganese (Mn), iridium (Ir), magnesium (Mg), copper (Cu), iron (Fe), nickel (Ni), chromium (Cr), cobalt (Co), or aluminum (Al), or the alloy thereof, more specifically, platinum manganese (PtMn) or iridium manganese (IrMn). The free layer 16 may be composed of, for example, the metal selected from the group consisting of chromium (Cr), manganese (Mn), cobalt (Co), iron (Fe), and nickel (Ni), and the alloy including one or more of these metals and exhibiting ferromagnetism. The free layer 16 may be composed of an alloy including these metals and at least one element of boron (B), carbon (C), or nitrogen (N). The alloy may be CoFe or CoFeB, for example.

Although not illustrated, the protective layer made of an insulator is present around the magnetoresistive element 200. The protective layer may be composed of, for example, silicon dioxide (SiO₂), silicon nitride (SiN), the silicon oxynitride film (SiON film), alumina (AlO₂), or the like. The protective layer covering the outer peripheral surface and the inner peripheral surface of the annular structure of the free layer 206 is also present on the outer peripheral surface and the inner peripheral surface. In the magnetoresistive element 200 configured as described above, current flows in the stacking direction by electrons tunneling through the insulating layer 204 to move from the reference layer 202 to the free layer 206 or from the free layer 206 to the reference layer 202. Since the magnetization direction of the free layer 206 changes in accordance with the magnitude of the magnetic field, an amount of tunneling current changes. By forming the free layer 206 into the annular structure, hysteresis characteristics of the magnetoresistive element 200 can be improved.

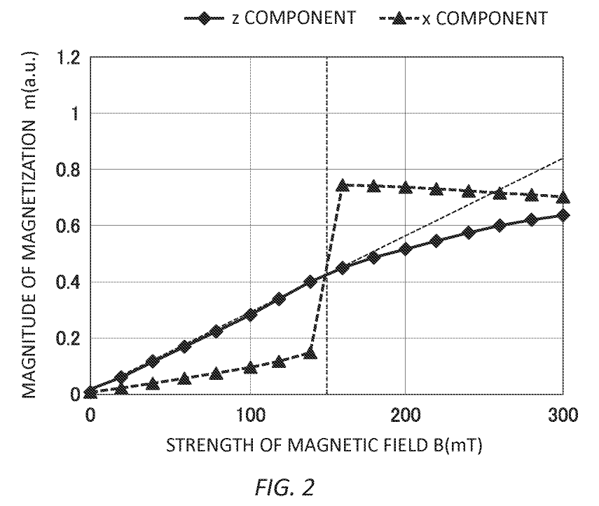

FIG. 2 shows, when a magnetic field is input in a state inclined by 30 degrees with respect to the direction (z-axis direction) perpendicular to the magnetoresistive element 200 having an annular structure, a state of changes, with respect to a change in the magnitude of the magnetic field, in the magnitude of magnetization in a lateral direction (x-axis direction) of magnetization of the free layer 206 and the magnitude of magnetization in a longitudinal direction (z-axis direction) of magnetization of the free layer 206.

The magnetization of the z-axis component is used as an output of the magnetoresistive element 200, but as shown in FIG. 2, when the magnitude B of the magnetic field becomes larger than a certain magnitude (for example, about 150 (MT)), linearity changes. This is due to the fact that, when the magnitude of the magnetic field exceeds a certain magnitude, the magnetization direction of the free layer 206 changes from a vortex direction to the magnetic field application direction, and the magnetization moment of a component in the x-axis direction greatly fluctuates. Since the magnetization moment in the x-axis direction or the y-axis direction discontinuously changes depending on the magnitude of the magnetic field, when a magnetic field is input in a state inclined with respect to the vertical direction (z-axis direction), linearity of an output of the magnetoresistive element 200 cannot be maintained, and there is a possibility that magnetic field detection accuracy of the magnetoresistive element 200 decreases.

In the case where the longitudinal magnetic field type magnetic sensor is used as a current sensor in this manner, in order not to reduce magnetic field detection accuracy, it is preferable to suppress components of the magnetic field in the x-axis direction and the y-axis direction.

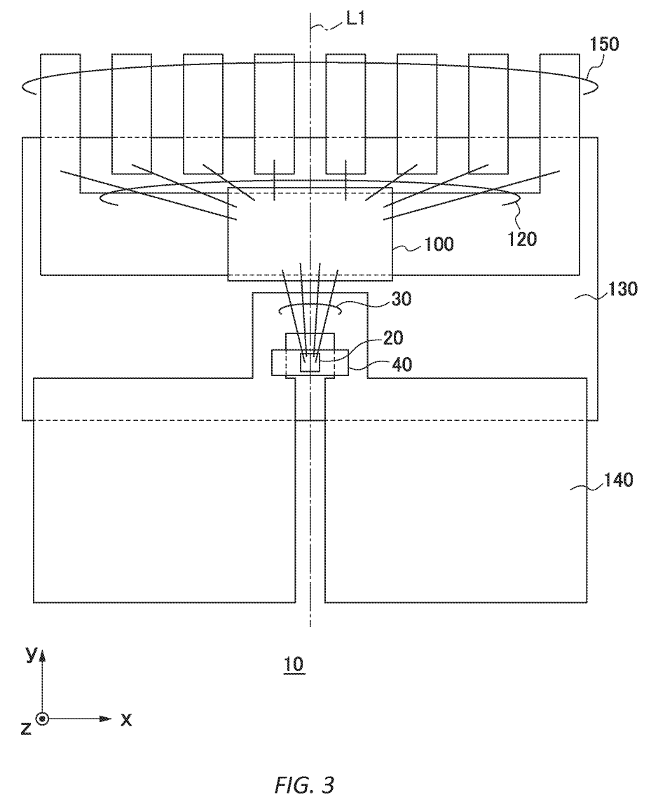

FIG. 3 is the schematic plan view of the current sensor 10 according to the first embodiment as viewed from a ceiling surface side (z-axis direction). In FIG. 3, coordinates are defined such that the direction parallel to the plane of the paper and from right to left is the x-axis direction, the direction parallel to the plane of the paper and from bottom to top is the y-axis direction, and the direction perpendicular to the plane of the paper and from back to front is the z-axis direction. Any one axis of the x-axis, the y-axis, or the z-axis is orthogonal to another axis.

The current sensor 10 includes a signal processing IC 100, a magnetoelectric conversion element 20, a conductor 140 that is a primary-side lead frame, a signal terminal 150 that is a secondary-side lead frame, and a sealing portion 130. The x-axis direction is the direction in which the two terminals of the conductor 140 and a plurality of terminals of the signal terminal 150 are arranged, and the y-axis is, in a plan view, the direction in which each of the two terminals of the conductor 140 and each of the plurality of terminals of the signal terminal 150 extends from the sealing portion 130. The z-axis direction is the direction intersecting the magnetic sensing surface of the magnetoelectric conversion element 20. The z-axis direction may be the direction perpendicular to the magnetic sensing surface of the magnetoelectric conversion element 20.

The measurement current to be measured by the magnetoelectric conversion element 20 flows through the conductor 140. The signal terminal 150 is electrically connected to the signal processing IC 100. The signal terminal 150 is electrically connected to the signal processing IC 100 via the wire 120. The signal terminal 150 is electrically insulated from the conductor 140.

The magnetoelectric conversion element 20 is electrically connected to the signal processing IC 100 via the wire 30. The magnetoelectric conversion element 20 may be the Hall element, the TMR element, or the GMR element. The magnetoelectric conversion element 20 may be the chip having the magnetic sensing surface that detects a magnetic field. If the magnetoelectric conversion element 20 is a Hall element, the magnetic sensing surface may be the semiconductor thin film. If the magnetoelectric conversion element 20 is a TMR element or a GMR element, the magnetic sensing surface may be the stacked structure including a reference layer, an insulating layer, and a free layer.

The magnetoelectric conversion element 20 may be arranged on the conductor 140 via an insulating sheet 40 such as a polyimide tape. The insulating sheet 40 is an example of the insulating layer. The magnetoelectric conversion element 20 outputs, to the signal processing IC 100, the signal to be processed by the signal processing IC 100. The wire 30 and the wire 120 may be formed of a conductive material mainly containing Au, Ag, Cu, or Al.

The signal processing IC 100 is arranged on the signal terminal 150 via the insulating sheet. The signal processing IC 100 is the large-scale integrated circuit (LSI). The signal processing IC 100 is the signal processing circuit made of a Si monolithic semiconductor formed on a Si substrate. The signal processing circuit processes an output signal according to the magnitude of the magnetic field output from the magnetoelectric conversion element 20.

The sealing portion 130 is made of a mold resin. The sealing portion 130 seals the magnetoelectric conversion element 20, a part of the conductor 140, the signal processing IC 100, and a part of the signal terminal 150 with the mold resin. The mold resin is made of, for example, the epoxy-based thermosetting resin to which silica is added, and may be molded into a semiconductor package by transfer molding.

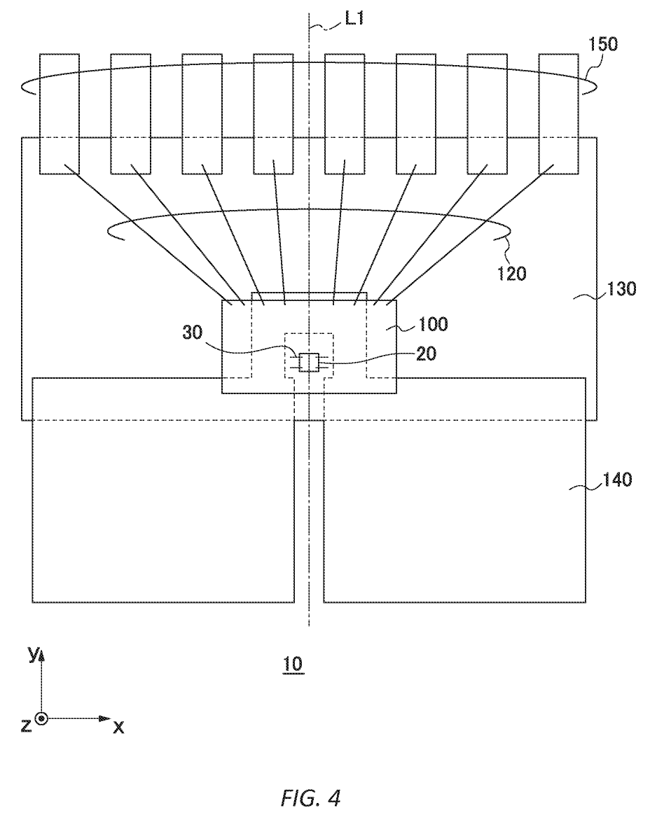

FIG. 4 is the schematic plan view of the current sensor 10 according to the second embodiment as viewed from the ceiling surface side (z-axis direction). In FIG. 4, coordinates are defined such that the direction parallel to the plane of the paper and from right to left is the x-axis direction, the direction parallel to the plane of the paper and from bottom to top is the y-axis direction, and the direction perpendicular to the plane of the paper and from back to front is the z-axis direction. Any one axis of the x-axis, the y-axis, or the z-axis is orthogonal to another axis.

The current sensor 10 according to the second embodiment differs from the current sensor 10 according to the first embodiment in that the signal processing IC 100 is arranged on the conductor 140 via the insulating sheet such as a polyimide tape (not illustrated). Furthermore, the current sensor 10 according to the second embodiment differs from the current sensor 10 according to the first embodiment in that the magnetoelectric conversion element 20 is arranged on the circuit surface of the signal processing IC 100. The magnetoelectric conversion element 20 is configured as the chip different from a chip constituting the signal processing IC 100. The magnetoelectric conversion element and the signal processing IC 100 may be connected via the through-silicon via (TSV) or a bump.

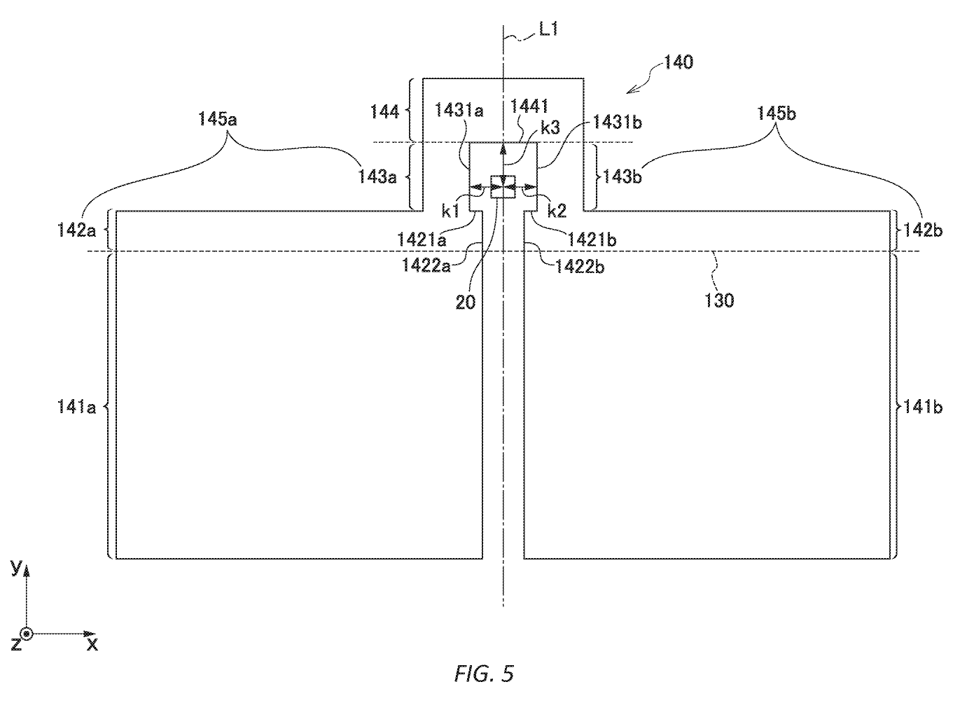

FIG. 5 is a plan view of the conductor 140 included in the current sensor 10 according to the first embodiment and the second embodiment. By using the conductor 140 having a shape as illustrated in FIG. 5, components of the magnetic field in the x-axis direction and the y-axis direction detected by the magnetoelectric conversion element 20 can be suppressed.

The conductor 140 has the substantially U-shape in plan view. In the present specification, the substantially U-shape is not limited to the illustrated U-shape, and includes various modified shapes that substantially achieve the same functions and effects. The conductor 140 has the first terminal portion 141a extending in the y-axis direction, and the second terminal portion 141b that is spaced apart from the first terminal portion 141a in the x-axis direction intersecting the y-axis direction and extends in the y-axis direction. The first terminal portion 141a and the second terminal portion 141b are exposed from the side surface of the sealing portion 130.

The conductor 140 further has the turn portion 144 spaced apart from the first terminal portion 141a and the second terminal portion 141b in the y-axis direction, and the first body portion 145a connected to the turn portion 144 and the first terminal portion 141a. The conductor 140 has the second body portion 145b that is spaced apart from the first body portion 145a in the x-axis direction and is connected to the turn portion 144 and the second terminal portion 141b. The turn portion 144, the first body portion 145a, and the second body portion 145b are not limited to being linear, and may have the rounded shape having curvature. Further, the x-axis-direction width of the turn portion 144 may be larger than a straight line connecting an outer contour line of the first body portion 145a and an outer contour line of the second body portion 145b in plan view.

The magnetoelectric conversion element 20 is arranged, in plan view, so as to be partially surrounded by the first body portion 145a, the turn portion 144, and the second body portion 145b, and detects the magnetic field generated by a current flowing through the conductor 140.

The first body portion 145a has the first flow path portion 143a extending in the y-axis direction and connected to the turn portion 144, and the first enlarged portion 142a connected to the first flow path portion 143a and the first terminal portion 141a, having a width larger than a width of the first flow path portion 143a in the x-axis direction, and protruding toward the second body portion 145b.

The second body portion 145b has the second flow path portion 143b extending in the y-axis direction and connected to the turn portion 144, and the second enlarged portion 142b connected to the second flow path portion 143b and the second terminal portion 141b, having a width larger than a width of the second flow path portion 143b in the x-axis direction, and protruding toward the first body portion 145b. The first flow path portion 143a and the second flow path portion 143b are spaced apart from each other in the x-axis direction.

The magnetoelectric conversion element 20 is located, in plan view, between the first flow path portion 143a and the second flow path portion 143b and at a position overlapping the center line L1 that is equidistant from a side 1431a of the first flow path portion 143a facing the second flow path portion 143b and a side 1431b of the second flow path portion 143b facing the first flow path portion 143a. In a plan view, a distance k1 between the centroid of the magnetoelectric conversion element 20 and the side 1431a of the first flow path portion 143a and a distance k2 between the centroid of the magnetoelectric conversion element 20 and the side 1431b of the second flow path portion 143b are equal.

The inner contour line of the conductor 140 is defined by the side 1422a of the first enlarged portion 142a facing the second enlarged portion 142b, the side 1421a of the first enlarged portion 142a facing the turn portion 144, the side 1431a, the side 1441, the side 1431b, the side 1421b of the second enlarged portion 142b facing the turn portion 144, and the side 1422b of the second enlarged portion 142b facing the first enlarged portion 142a. The inner contour line of the conductor 140 is line-symmetric about the center line L1 in a plan view.

In a plan view, each of the distance k1 between the centroid of the magnetoelectric conversion element 20 and the side 1431a of the first flow path portion 143a and the distance k2 between the centroid of the magnetoelectric conversion element 20 and the side 1431b of the second flow path portion 143b is smaller than the distance k3 between the centroid of the magnetoelectric conversion element 20 and the side 1441 of the turn portion 144 facing the magnetoelectric conversion element 20 in a plan view.

The cross-sectional area of the turn portion 144 is larger than each cross-sectional area of the first flow path portion 143a and the second flow path portion 143b. The cross-sectional area of the turn portion 144 may be the cross-sectional area of the turn portion 144 in a yz plane. Each cross-sectional area of the first flow path portion 143a and the second flow path portion 143b may be the cross-sectional area of each of the first flow path portion 143a and the second flow path portion 143b in an xz plane.

The reason why, by configuring the conductor 140 in such a configuration, components of the magnetic field in the x-axis direction and the y-axis direction detected by the magnetoelectric conversion element 20 can be suppressed will be described below with reference to results of the electromagnetic field simulation by a finite element method.

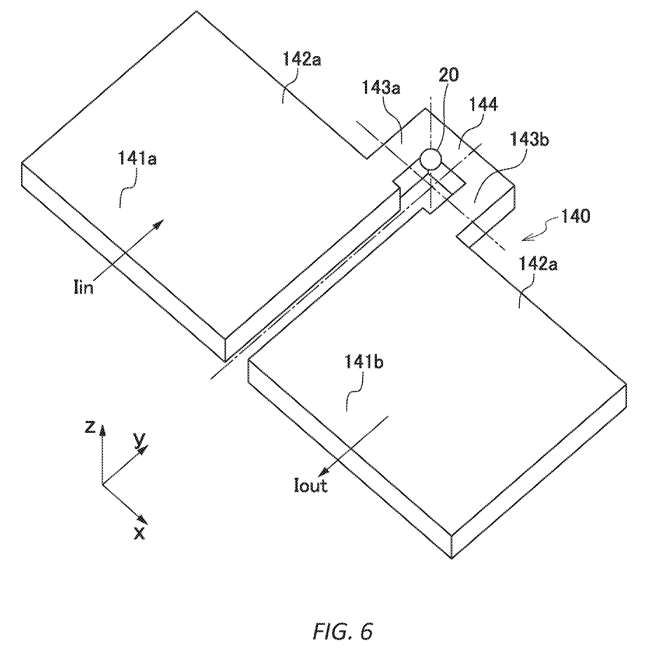

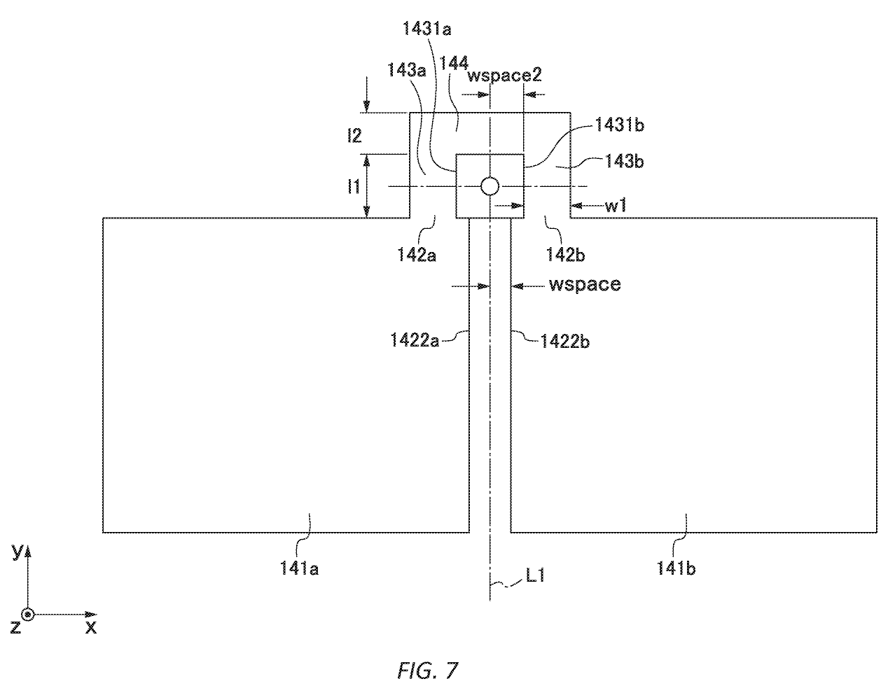

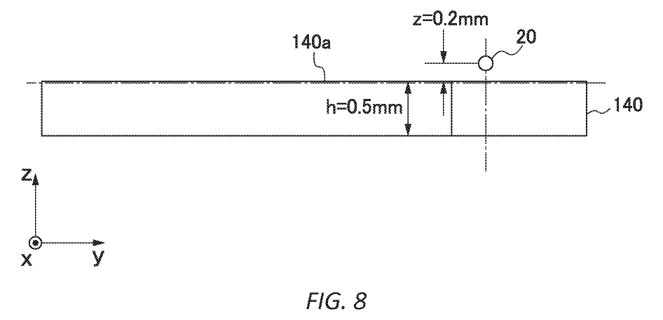

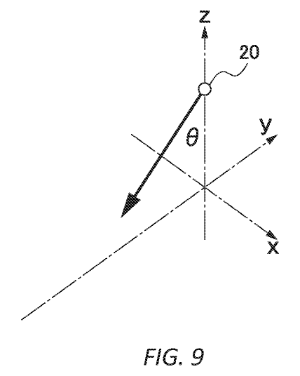

FIG. 6 is a perspective view illustrating the positional relationship between the conductor 140 and the magnetoelectric conversion element 20 used in the simulation. FIG. 7 is a plan view of the conductor 140 and the magnetoelectric conversion element 20 used in the simulation. FIG. 8 is the side view of the conductor 140 and the magnetoelectric conversion element 20 used in the simulation as viewed from the x-axis direction. FIG. 9 is a diagram for describing the tilt angle θ used in the simulation.

As illustrated in FIG. 7, in the conductor 140 used in the simulation, the x-axis-direction width of the second flow path portion 143b (the first flow path portion 143a) is defined as w1, and the y-axis-direction length is defined as l1. The y-axis-direction width of the turn portion 144 is defined as l2. The distance from the center line L1 to the side 1422b (the side 1422a) of the second enlarged portion 142b (the first enlarged portion 142a) is defined as wspace, and the distance from the center line L1 to the side 1431b (the side 1431a) of the second flow path portion 143b (the first flow path portion 143a) is defined as wspace2.

As illustrated in FIG. 8, the thickness h of the conductor 140 is set to 0.5 mm. The magnetoelectric conversion element 20 is set to have a distance of 0.2 mm from the surface 140a on the ceiling surface side of the conductor 140. As illustrated in FIG. 9, the inclination of the magnetic flux density vector from the z-axis at the position of the magnetoelectric conversion element 20 derived by the simulation is defined as the tilt angle θ.

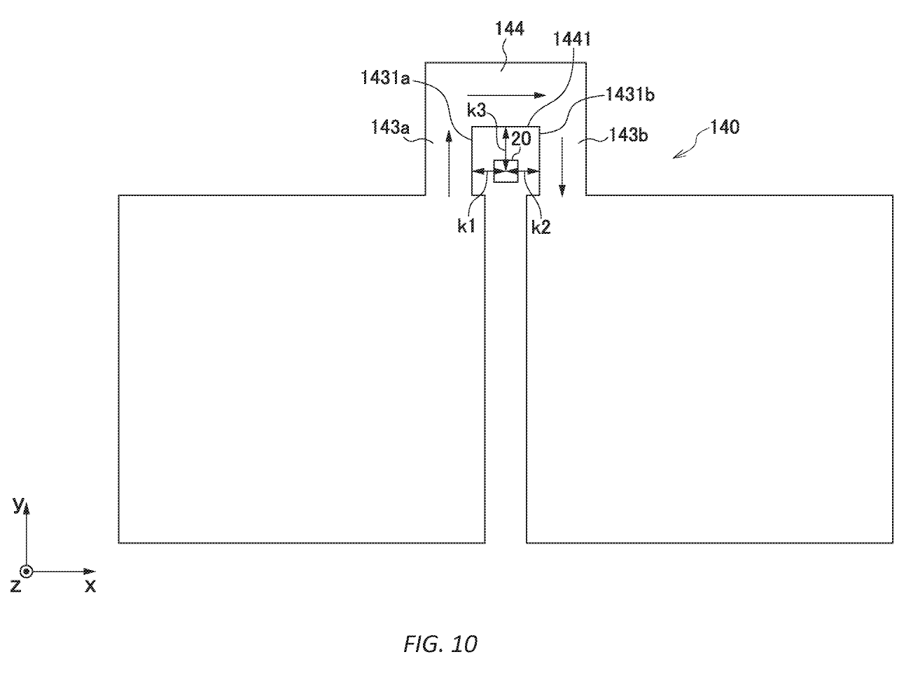

In the conductor 140 configured as described above, as illustrated in FIG. 7, the current Iin is input from the first terminal portion 141a, and the current Iout is output from the second terminal portion 141b. In this case, as illustrated in FIG. 10, currents of the same magnitude flow through the first flow path portion 143a and the second flow path portion 143b in opposite directions in the y-axis direction. The xy component of the magnetic field, in the region surrounded by the inner contour line of the conductor 140, generated by a current flowing through the first flow path portion 143a is opposite in direction to the xy component of the magnetic field, in the region surrounded by the inner contour line of the conductor 140, generated by a current flowing through the second flow path portion 143b. Therefore, by arranging the magnetoelectric conversion element 20 at an intermediate position between the side 1431a of the first flow path portion 143a and the side 1431b of the second flow path portion 143b, it is possible to suppress an influence on the magnetoelectric conversion element 20, the influence caused by the xy component of the magnetic field generated by currents flowing through the first flow path portion 143a and the second flow path portion 143b.

On the other hand, the xy component of the magnetic field, in the region surrounded by the inner contour line of the conductor 140, generated by a current flowing through the turn portion 144 is difficult to cancel because there is no portion through which a current of the same magnitude flows in a direction opposite to that of the current flowing through the turn portion 144. Therefore, in order to suppress an influence of the xy component while maintaining the z component of the magnetic field to the magnetoelectric conversion element 20, it is preferable that, in a plan view, each of the distance k1 between the centroid of the magnetoelectric conversion element 20 and the side 1431a of the first flow path portion 143a and the distance k2 between the centroid of the magnetoelectric conversion element 20 and the side 1431b of the second flow path portion 143b is smaller than the distance k3 between the centroid of the magnetoelectric conversion element 20 and the side 1441 of the turn portion 144 facing the magnetoelectric conversion element 20 in a plan view.

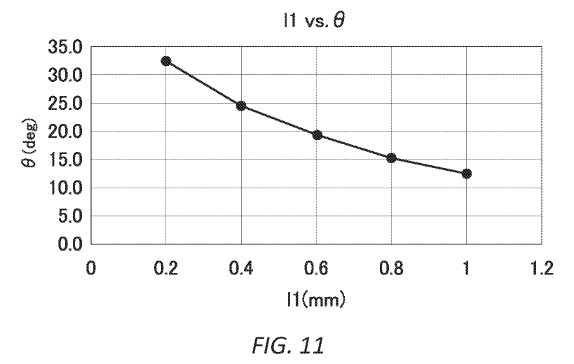

FIG. 11 illustrates, as a result of the simulation, a relationship between the y-axis-direction length l1 of the second flow path portion 143b (the first flow path portion 143a) and the tilt angle θ. In the simulation, the magnitude of the tilt angle θ in a case where the x-axis-direction width w1 of the second flow path portion 143b (the first flow path portion 143a) is 0.5 mm, the distance wspace2 from the center line L1 to the side 1431b (the side 1431a) of the second flow path portion 143b (the first flow path portion 143a) is 0.4 mm, the y-axis-direction width l2 of the turn portion 144 is 0.5 mm, and the length l1 is from 0.2 mm to 1 mm is shown.

As illustrated in FIG. 11, as the y-axis-direction length l1 of the second flow path portion 143b (the first flow path portion 143a) is longer, the tilt angle θ becomes smaller. As the length l1 is longer, the turn portion 144 can be moved away from the magnetoelectric conversion element 20, and thus it is possible to suppress an influence on the magnetoelectric conversion element 20, the influence caused by xy components of the magnetic field generated by the current flowing through the turn portion 144.

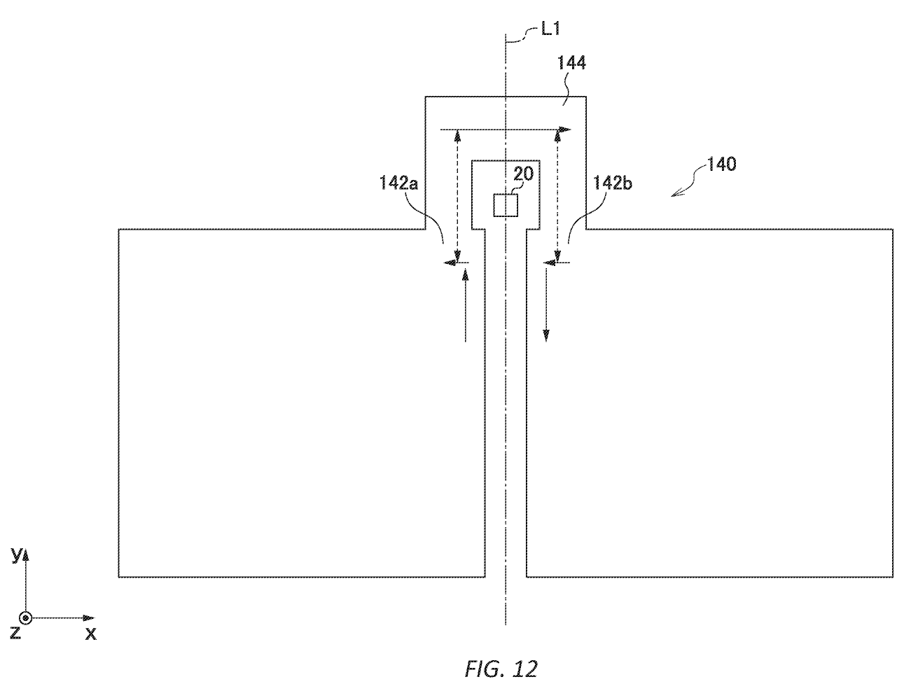

In addition, since the first enlarged portion 142a and the second enlarged portion 142b each protrude toward the center line L1, as illustrated in FIG. 12, the current flows so as to wrap around the inner contour line. Accordingly, the current flowing in a direction opposite to that of the current flowing through the turn portion 144 appears. Due to xy components of the magnetic field generated by the current flowing in the opposite direction, xy components of the magnetic field generated by the current flowing through the turn portion 144 are mitigated, and an influence on the magnetoelectric conversion element 20 can be suppressed.

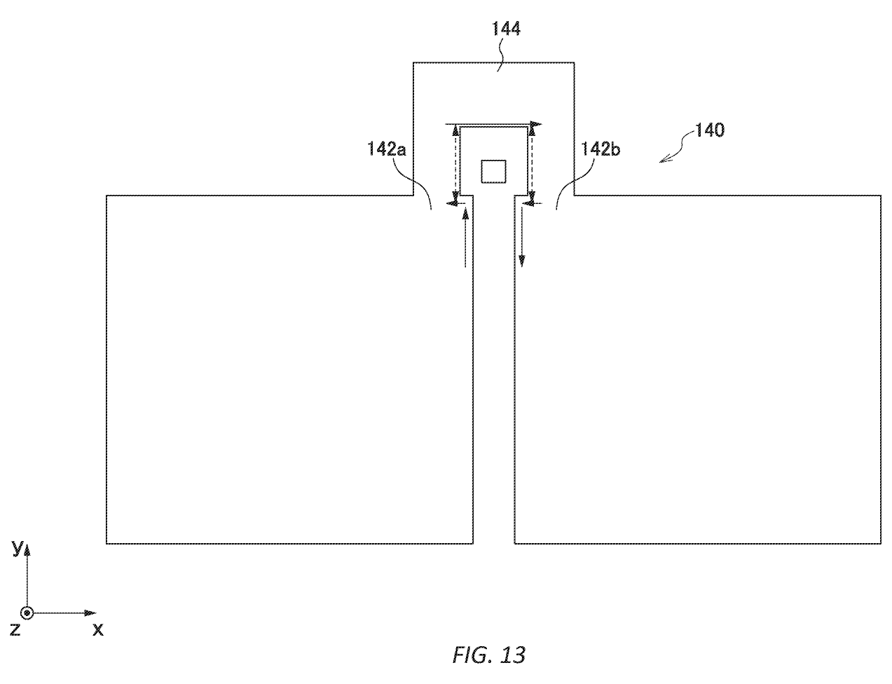

In particular, when the current flowing through the conductor 140 is the high-frequency current, as illustrated in FIG. 13, due to a proximity effect, the current flowing through the conductor 140 shifts toward an inner contour line side. Therefore, the distance between the current flowing through the first enlarged portion 142a and the second enlarged portion 142b and the current flowing through the turn portion 144 becomes shorter, xy components of respective magnetic fields can be canceled more effectively, and an influence of xy components of the magnetic field on the magnetoelectric conversion element 20 can be suppressed.

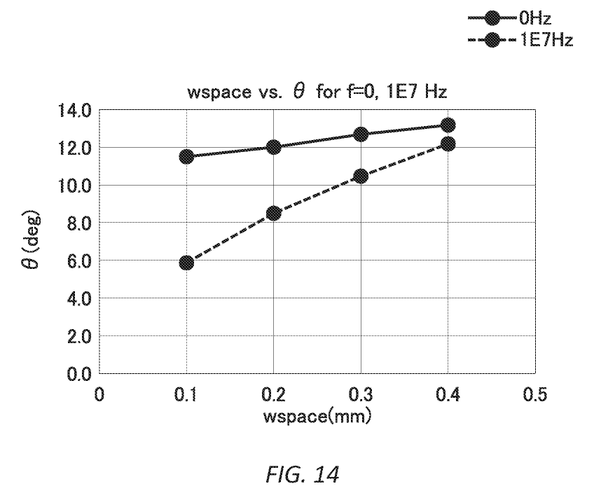

FIG. 14 illustrates, as simulation results, a relationship between the distance wspace from the center line L1 to the side 1422b (the side 1422a) of the second enlarged portion 142b (the first enlarged portion 142a) and the tilt angle θ, in a case where each of the low-frequency current (f=0 Hz) and the high-frequency current (f=1E7 Hz) is caused to flow through the conductor 140.

In both of the case of the low-frequency current and the case of the high-frequency current, as the distance wspace is shorter, that is, as a protrusion amount of the first enlarged portion 142 and the second enlarged portion 142b toward the center line L1 side is larger, a larger amount of current flows through the protruding portions, and thus xy components of respective magnetic fields can be canceled more effectively, and the tilt angle θ can be reduced. In particular, in the case of the high-frequency current, an effect of being able to reduce the tilt angle θ becomes greater. This effect is useful in the current sensor application in that, when the surge current that can flow instantaneously as an excessive current and can adversely affect a power conversion device is generated, highly accurate measurement can be realized with the current sensor.

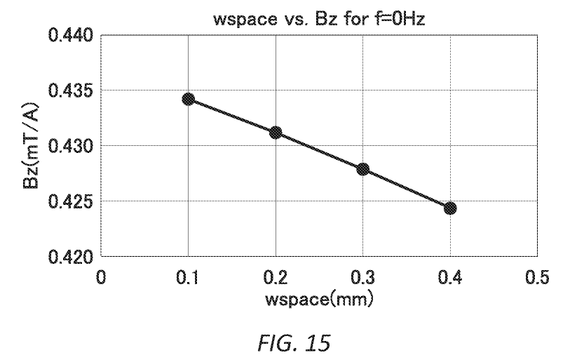

FIG. 15 illustrates, as simulation results, a relationship between the distance wspace from the center line L1 to the side 1422b (the side 1422a) of the second enlarged portion 142b (the first enlarged portion 142a) and the magnitude of the magnetic field detected by the magnetoelectric conversion element 20. Reducing the distance wspace means increasing the protruding portions of the first enlarged portion 142a and the second enlarged portion 142b. Therefore, when the distance wspace is reduced, the protruding portions become larger, and thus the current flowing through the protruding portions increases, and the current flowing around the magnetoelectric conversion element 20 increases. Therefore, by reducing the distance wspace, the magnitude of the magnetic field of a z-axis component detected by the magnetoelectric conversion element 20 can be increased.

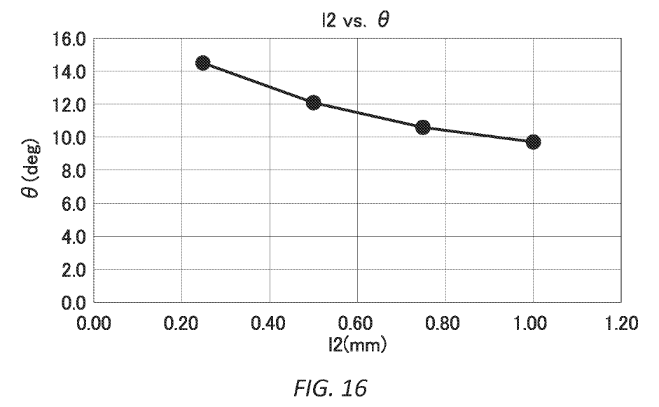

FIG. 16 illustrates, as simulation results, a relationship between the y-axis-direction width l2 of the turn portion 144 and the tilt angle θ. When the y-axis-direction width l2 of the turn portion 144 is large, the density of the current flowing through the turn portion 144 comes to be distributed also in a location away from the magnetoelectric conversion element 20, and thus it is possible to suppress an influence on the magnetoelectric conversion element 20, the influence caused by xy components of the magnetic field generated by the current flowing through the turn portion 144. On the other hand, even if the x-axis-direction widths of the first flow path portion 143a and the second flow path portion 143b are narrow, influences of xy components of respective magnetic fields cancel each other out, and thus an influence of xy components of the magnetic field on the magnetoelectric conversion element 20 does not change, and currents flowing through the first flow path portion 143a and the second flow path portion 143b approach the magnetoelectric conversion element 20, and thus the magnitude of the magnetic field of the z-axis component detected by the magnetoelectric conversion element 20 can be increased. Accordingly, the y-axis-direction width l2 of the turn portion 144 is preferably larger than the x-axis-direction width of the second flow path portion 143b. That is, the area of the turn portion 144 in plan view is preferably larger than the area of each of the first flow path portion 143a and the second flow path portion 143b in plan view.

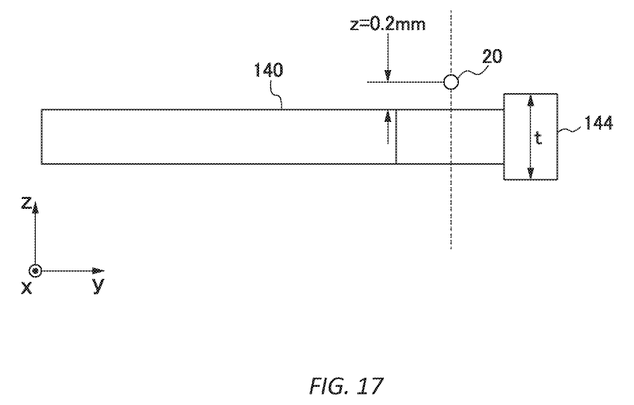

FIG. 17 illustrates the shape of the conductor 140 used in the simulation. With the z-direction thickness of the turn portion 144 being t, the magnitude of the magnetic field detected by the magnetoelectric conversion element 20 and the tilt angle θ are simulated by changing t.

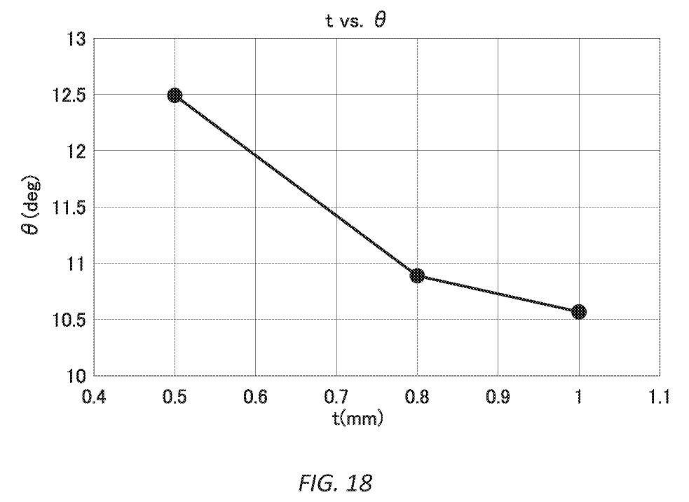

FIG. 18 illustrates, as simulation results, a relationship between the z-axis-direction thickness t of the turn portion 144 and the tilt angle θ. By increasing the z-axis-direction thickness t of the turn portion 144, symmetry of the distribution of the current flowing through the turn portion 144 with respect to the magnetic sensing surface of the magnetoelectric conversion element 20 is improved, and thus when the z-axis-direction thickness t of the turn portion 144 is increased, the tilt angle θ decreases. The position of the magnetoelectric conversion element 20 may be arranged above the signal processing IC 100 located on the conductor. Therefore, in order to improve symmetry of a current distribution, it is necessary to make the thickness in the z direction of the first flow path portion 143a and the thickness in the z direction of the second flow path portion 143b smaller than the thickness in the z direction of the turn portion 144. That is, the cross-sectional area of the turn portion 144 is preferably larger than each cross-sectional area of the first flow path portion 143a and the second flow path portion 143b.

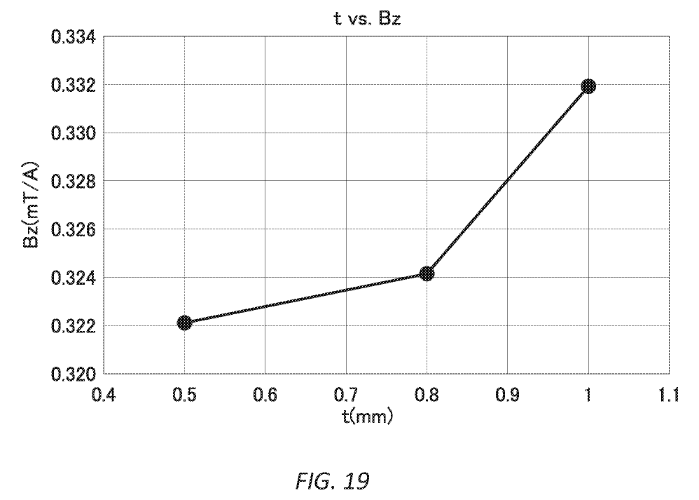

FIG. 19 shows, as the simulation result, a relationship between the z-axis-direction thickness t of the turn portion 144 and the magnitude of the magnetic field detected by the magnetoelectric conversion element 20. By increasing the thickness t in the z-axis direction of the turn portion 144, the magnetic sensing surface of the magnetoelectric conversion element 20 and a current path come closer to each other, and thus, when the z-axis-direction thickness t of the turn portion 144 is increased, the magnitude of the magnetic field detected by the magnetoelectric conversion element 20 increases. The position of the magnetoelectric conversion element 20 may be arranged above the signal processing IC 100 located on the conductor. Therefore, in order to bring the current path closer to the magnetic sensing surface of the magnetoelectric conversion element 20, it is necessary to make the thickness in the z direction of the first flow path portion 143a and the thickness in the z direction of the second flow path portion 143b smaller than the thickness in the z direction of the turn portion 144. That is, the cross-sectional area of the turn portion 144 is preferably larger than each cross-sectional area of the first flow path portion 143a and the second flow path portion 143b. Note that the z-axis-direction thickness t may extend asymmetrically with respect to the first flow path portion 143a and the second flow path portion 143b.

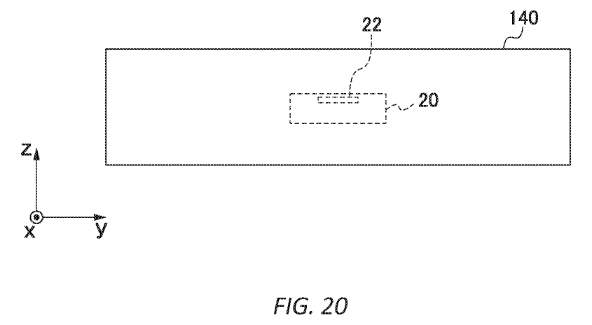

In the above description, as shown in FIG. 8, description has been made on the assumption that the magnetoelectric conversion element 20 is located at the height different from that of the conductor 140 in the z-axis direction. Thus, when the magnetoelectric conversion element 20 and the conductor 140 have different heights in the z-axis direction, the xy-component magnetic field generated by current flowing through the conductor 140 is more likely to affect the magnetoelectric conversion element 20. However, when the difference in height in the z-axis direction between the magnetoelectric conversion element 20 and the conductor 140 is small, that is, as shown in FIG. 20, when the magnetic sensing surface 22 of the magnetoelectric conversion element 20 and the conductor 140 overlap when viewed from the x-axis direction (in a side view), an influence on the magnetoelectric conversion element 20, the influence caused by the xy-component magnetic field generated by current flowing through the conductor 140, can be suppressed.

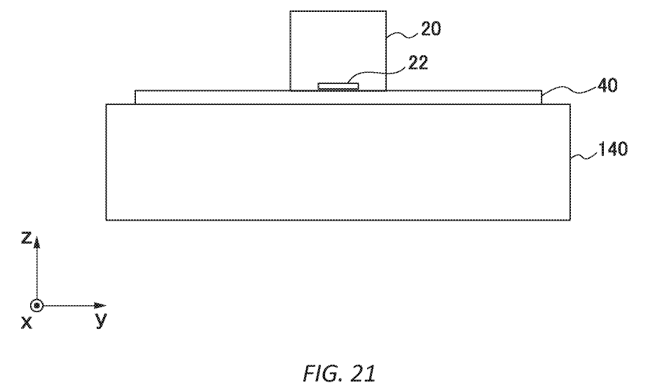

Even when the magnetic sensing surface 22 of the magnetoelectric conversion element 20 is not arranged at a position overlapping the conductor 140 in a side view, as shown in FIG. 21, when the magnetoelectric conversion element 20 is arranged on the conductor 140 via the insulating sheet 40, by arranging the magnetoelectric conversion element 20 such that the magnetic sensing surface 22 of the magnetoelectric conversion element 20 faces the conductor 140, a difference between a height in the z-axis direction of the magnetic sensing surface 22 of the magnetoelectric conversion element 20 and a height in the z-axis direction of the conductor 140 can be reduced. Accordingly, an influence on the magnetoelectric conversion element 20, the influence caused by the xy-component magnetic field generated by current flowing through the conductor 140, can be suppressed.

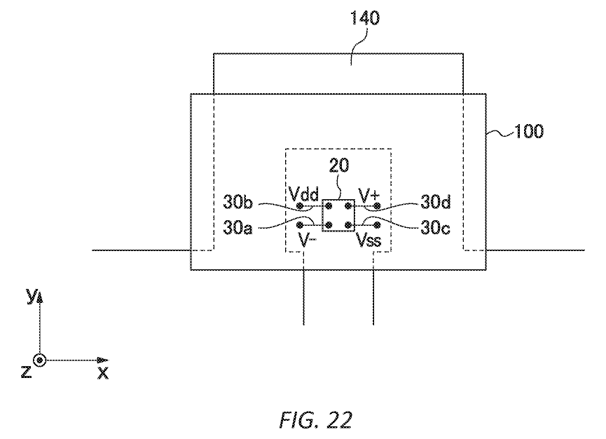

FIG. 22 is an enlarged view illustrating the peripheral portion including the magnetoelectric conversion element 20 of the current sensor 10 according to the second embodiment shown in FIG. 4.

The magnetoelectric conversion element 20 has a Vdd terminal, a Vss terminal, a V+ terminal, and a V- terminal. The Vdd terminal and the Vss terminal are the power supply terminals of the magnetoelectric conversion element 20, and the V+ terminal and the V- terminal are the output terminals of the magnetoelectric conversion element 20. The Vdd terminal and the V+ terminal are arranged to face each other in the x-axis direction, and the V- terminal and the Vss terminal are arranged to face each other. The Vdd terminal and the V- terminal are arranged to face each other in the y-axis direction, and the V+ terminal and the Vss terminal are arranged to face each other in the y-axis direction.

The V- terminal is electrically connected to the signal processing IC 100 via the wire 30a, and the Vdd terminal is electrically connected to the signal processing IC 100 via the wire 30b. The Vss terminal is electrically connected to the signal processing IC 100 via the wire 30c, and the V+ terminal is electrically connected to the signal processing IC via the wire 30d.

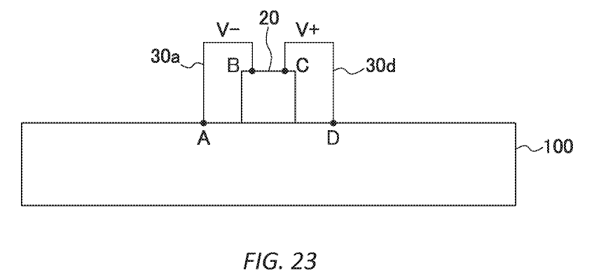

FIG. 23 is a side view of the magnetoelectric conversion element 20 and the signal processing IC 100. In FIG. 23, among four lines, only the wire 30a and the wire 30d are shown. The wire 30a electrically connects the pad A of the signal processing IC 100 and the pad B of the magnetoelectric conversion element 20, and the wire 30d electrically connects the pad D of the signal processing IC 100 and the pad C of the magnetoelectric conversion element 20. Here, the plane parallel to an xy plane and including the pad A and the pad D of the signal processing IC 100 and the plane parallel to the xy plane and including the pad B and the pad C of the magnetoelectric conversion element 20 are different planes, and the line segment connecting the pad A and the pad B and the line segment connecting the pad C and the pad D do not intersect because, when they intersect when viewed from the z-axis direction, they contact each other and may short-circuit.

When each pad has such a positional relationship, the magnetic flux loop is formed that returns to the pad A via the pad A, the wire 30a, the pad B, the pad C, the wire 30d, and the pad D in this order. When the magnetic flux linkage generated by a current flowing through the conductor 140 penetrates this magnetic flux loop, an induced electromotive force is generated, and so-called dl/dt noise is generated in the wire 30a and the wire 30d. In order to suppress dl/dt noise, it is necessary to devise the arrangement of the pads so that the magnetic flux linkage penetrating the magnetic flux loop becomes zero.

Since the magnetic field detected by the magnetoelectric conversion element 20 is a z-axis component, the direction of the magnetic flux is assumed to be the z-axis direction. In this case, in order to suppress dl/dt noise, it is sufficient to make the magnetic flux linkage penetrating the magnetic flux loop zero when viewed from the z-axis direction.

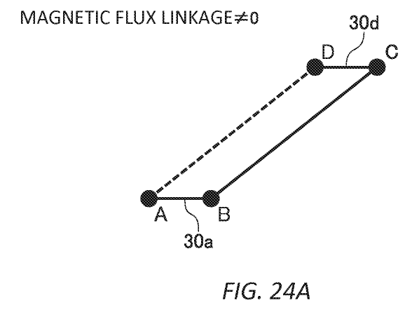

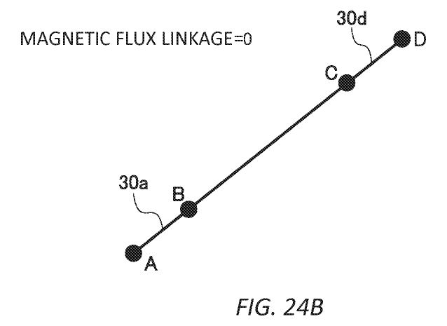

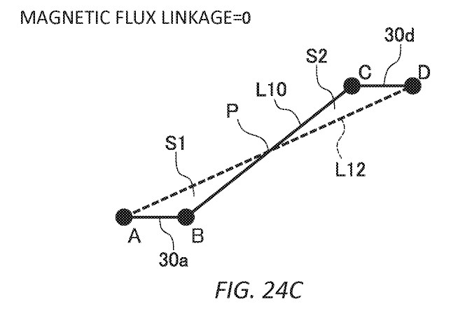

For example, when the magnetic flux loop as illustrated in FIG. 24A is formed, the magnetic flux linkage does not become zero. On the other hand, as illustrated in FIG. 24B, when the pad A of the signal processing IC 100 and the pad B of the magnetoelectric conversion element 20 that are connected to the wire 30a, and the pad C of the magnetoelectric conversion element and the pad D of the signal processing IC 100 that are connected to the wire 30d, are arranged on the straight line in plan view, the magnetic flux linkage can be made zero.

Alternatively, as illustrated in FIG. 24C, when the first line segment L10 connecting the pad B of the magnetoelectric conversion element 20 and the pad C of the magnetoelectric conversion element and the second line segment L12 connecting the pad A of the signal processing IC 100 and the pad D of the signal processing IC 100 are in a skew positional relationship with each other in plan view, and the first line segment L10 and the second line segment L12 have an intersection point P in plan view, and an area in plan view of the first triangle S1 having the intersection point P, the pad B, and the pad A as vertices and an area in plan view of the second triangle S2 having the intersection point P, the pad C, and the pad D as vertices are equal to each other, the magnetic flux linkage can be made zero. That the areas are equal to each other is the concept including being substantially equal. A ratio between the area in plan view of the first triangle S1 having the intersection point P, the pad B, and the pad A as vertices and the area in plan view of the second triangle S2 having the intersection point P, the pad C, and the pad D as vertices is in a range from 0.5 to 1.5, preferably in a range from 0.75 to 1.25, and more preferably in a range from 0.9 to 1.1.

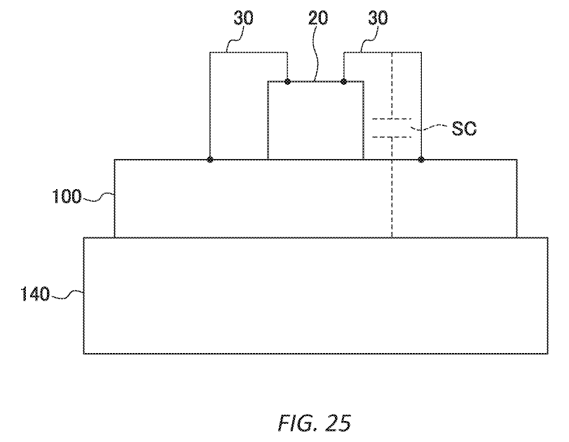

When the signal processing IC 100 and the magnetoelectric conversion element 20 are connected via the wire 30, the wire 30 is arranged in the vicinity of the conductor 140. In such a configuration, when the potential of the conductor 140 changes rapidly, as illustrated in FIG. 25, the change in potential propagates to the wire 30 via the parasitic capacitance SC formed between the wire 30 and the conductor 140, and so-called dV/dt noise is generated. Here, the parasitic capacitance SC is determined by the distance between the conductor 140 and the wire 30, the length of the wire 30 when viewed from the z-axis direction, the diameter of the wire, and a dielectric constant of a material separating the conductor 140 and the wire 30.

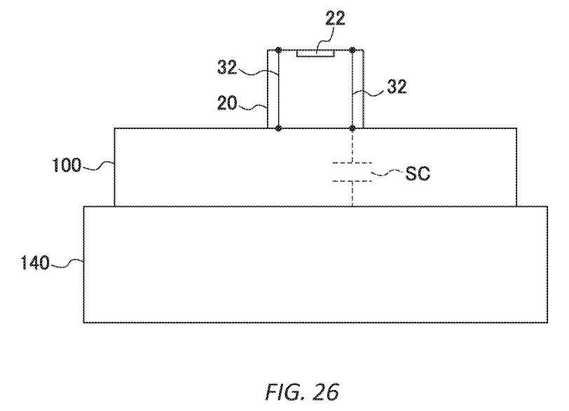

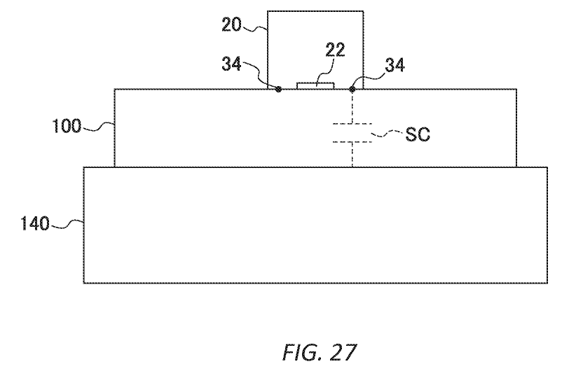

In order to suppress such dV/dt noise, as illustrated in FIG. 26, when the magnetic sensing surface 22 of the magnetoelectric conversion element 20 is present on a surface opposite to a surface facing the signal processing IC 100, the magnetoelectric conversion element 20 and the signal processing IC 100 may be electrically connected via the through-silicon via (TSV) 32 penetrating from a surface on which the magnetic sensing surface 22 of the magnetoelectric conversion element 22 is present toward a surface of the magnetoelectric conversion element 22 facing the signal processing IC 100. Accordingly, when viewed from the z-axis direction, the TSV 32 is the point, and a wire length is substantially zero, and the parasitic capacitance SC such as that in the case where the wire 30 is present as in FIG. 25 is not formed. Alternatively, as illustrated in FIG. 27, when the magnetic sensing surface 22 of the magnetoelectric conversion element 20 is present on the surface facing the signal processing IC 100, the magnetoelectric conversion element 20 may be configured as a flip chip, and the magnetoelectric conversion element 20 and the signal processing IC 100 may be electrically connected via a bump 34. The bump 34 is the point when viewed from the z-axis direction, and a wire length is substantially zero. Therefore, when the signal processing IC 100 and the magnetoelectric conversion element 20 are electrically connected by the TSV 32 or the bump 34, the parasitic capacitance SC between conductor 140 and wire 30 is eliminated, and thus dV/dt noise can be suppressed. Furthermore, since the wire 30 is not present, a magnetic flux loop is not formed, and, when viewed from the z-axis direction, the magnetic flux linkage becomes zero, and dl/dt noise can be suppressed.

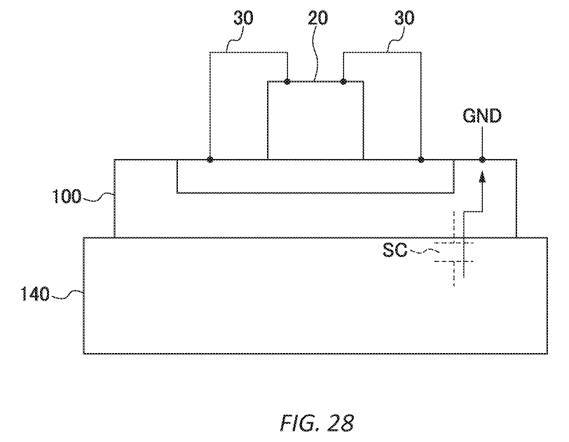

When the signal processing IC 100 and the magnetoelectric conversion element 20 are connected via the wire 30, as illustrated in FIG. 28, when the substrate potential of the signal processing IC 100 is connected to ground (GND), parasitic capacitance formed between the conductor 140 and the wire 30 is eliminated by capacitive shielding.

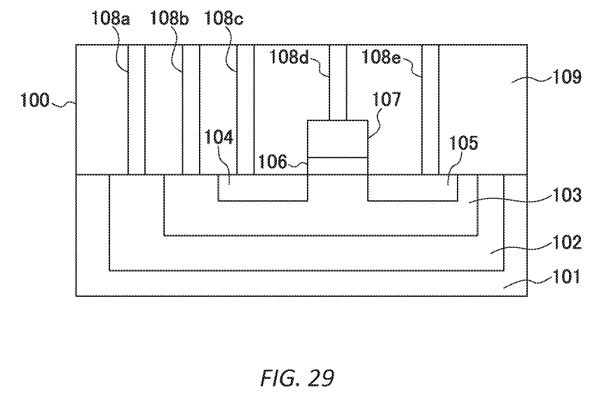

FIG. 29 illustrates an example of a cross section of the signal processing IC 100. The signal processing IC 100 includes a non-doped substrate 101, an n-type deep well 102 arranged on the substrate 101, a p-type well 103 arranged on the n-type deep well 102, an n-type source 104 and an n-type drain 105 arranged on the p-type well 103, a gate insulating film 106 arranged on the p-type well 103 interposed between the n-type source 104 and the n-type drain 105, and a gate electrode 107 arranged on the gate insulating film 106. The signal processing IC 100 further includes the via 108a connected to the n-type deep well 102, the via 108b connected to the p-type well 103, the via 108c connected to the n-type source 104, the via 108d connected to the gate electrode 107, and the via 108e connected to the n-type drain 105. The signal processing IC 100 further includes the interlayer insulating film 109 covering around each of the vias 108a to 108e, the gate insulating film 106, and the gate electrode 107.

The substrate 101, the n-type deep well 102, the p-type well 103, the n-type source 104, and the n-type drain 105 may include single-crystal silicon. Among the n-type deep well 102, the p-type well 103, the n-type source 104, and the n-type drain 105, the n-type source 104 and the n-type drain 105 have the highest doping concentration, and the n-type deep well 102 has the lowest doping concentration. The doping concentration of the p-type well 103 is the concentration between the doping concentrations of the n-type source 104 and the n-type drain 105 and the doping concentration of the n-type deep well 102. The gate insulating film 106 may include silicon dioxide (SiO₂). The gate electrode 107 may include polycrystalline silicon. Each of the vias 108a to 108e may include tungsten (W). The interlayer insulating film 109 may include silicon dioxide (amorphous).

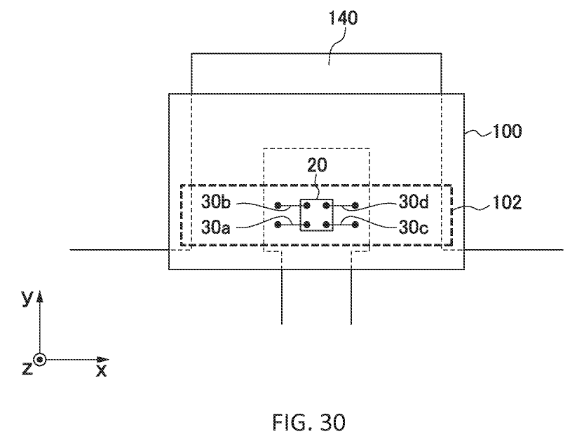

The n-type deep well 102, which is the impurity region, is connected to ground (GND) via the via 108a. As illustrated in FIG. 30, when the wire 30a, the wire 30b, the wire 30c, and the wire 30d overlap the region of the n-type deep well 102 as viewed from a z-axis direction, capacitive shielding is provided between the wire 30a, the wire 30b, the wire 30c, and the wire 30d and the conductor 140, and the parasitic capacitance SC is eliminated. Thus, dV/dt noise can be suppressed.

The magnetoelectric conversion element 20 described above may be the magnetoresistive element, and may be the tunnel magnetoresistive (TMR) element or the giant magnetoresistive (GMR) element.

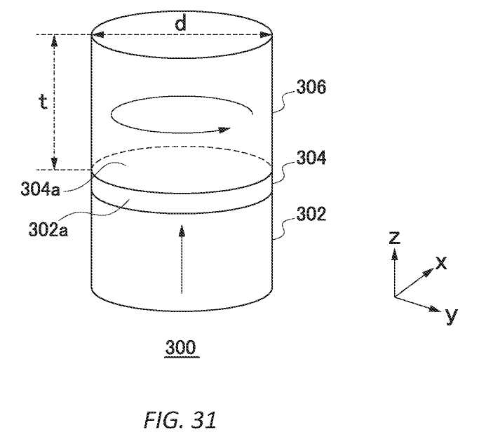

FIG. 31 illustrates an example of the structure of the magnetoresistive element 300. The magnetoresistive element 300 is the vortex-type TMR element. The magnetoresistive element 300 has a stacked structure including the reference layer 302, the insulating layer 304 arranged above the surface 302a of the reference layer 302, and the free layer 306 arranged above the surface 304a of the insulating layer 304 on an opposite side from the surface facing the reference layer 302. The magnetoresistive element 300 may include, below the reference layer 302, the seed layer that contributes to planarization of an interface and serves as a starting point for growth of a layer stacked above the seed layer. The magnetoresistive element 300 may include, above the free layer 306, the cap layer that is a member stacked on the free layer 306 and covering the stacked body from above.

The magnetization direction of the free layer 306 is present in the in-plane direction along the layer, and may be present, in the zero magnetic field state, in a clockwise direction or a counterclockwise direction along the in-plane direction along the layer.

The magnetization direction of the reference layer 302 intersects the x-axis direction and the y-axis direction, and is present in the z-axis direction along the stacking direction of the stacked structure. Here, that the magnetization direction of the reference layer 302, also referred to as a fixed layer, is the z-axis direction (vertical direction) intersecting the layer surface can be identified from the fact that a magnetoresistance change ΔR has a certain pattern.

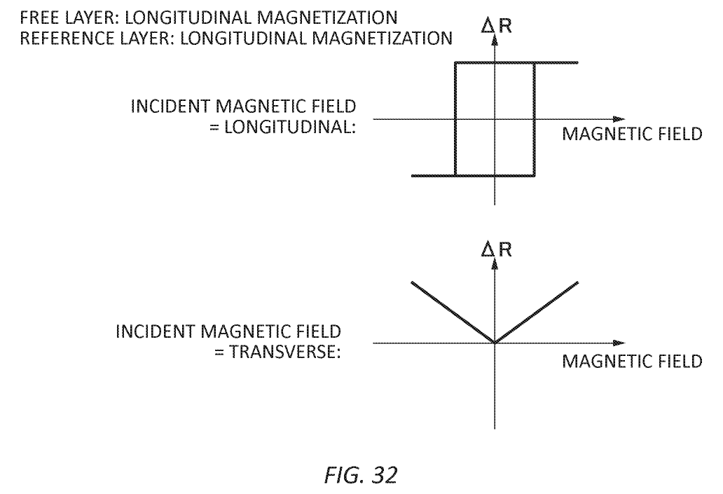

FIG. 32 illustrates a relationship between the magnitude of the magnetic field and the magnetoresistance change ΔR when the incident magnetic field is the longitudinal magnetic field (z-axis), and a relationship between the magnitude of the magnetic field and the magnetoresistance change ΔR when the incident magnetic field is the transverse magnetic field (x-axis or y-axis), in a case where the magnetization direction of the free layer 306 is longitudinal (z-axis direction) and the magnetization direction of the reference layer 302 is longitudinal (z-axis direction). When the relationship between the magnitude of the magnetic field and the magnetoresistance change ΔR has a pattern as illustrated in FIG. 29, the magnetization direction of the reference layer 302 is longitudinal (z-axis direction).

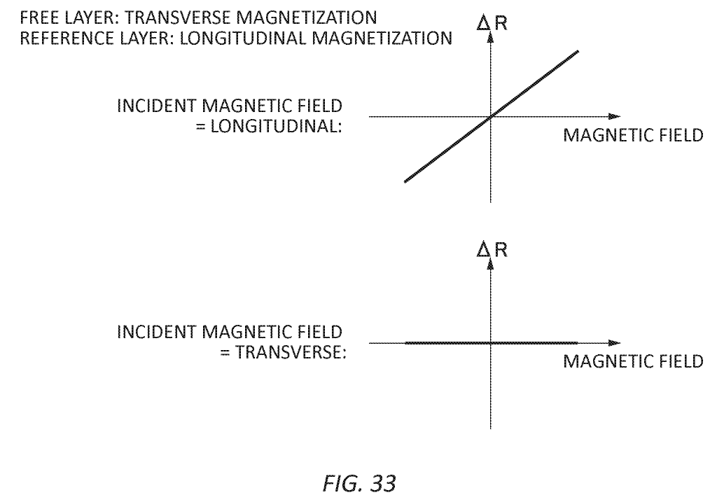

FIG. 33 illustrates a relationship between the magnitude of the magnetic field and the magnetoresistance change ΔR when the incident magnetic field is the longitudinal magnetic field (z-axis), and a relationship between the magnitude of the magnetic field and the magnetoresistance change ΔR when the incident magnetic field is the transverse magnetic field (x-axis or y-axis), in a case where the magnetization direction of the free layer 306 is transverse (x-axis or y-axis direction) and the magnetization direction of the reference layer 302 is longitudinal (z-axis direction). When the relationship between the magnitude of the magnetic field and the magnetoresistance change ΔR has the pattern as illustrated in FIG. 33, the magnetization direction of the reference layer 302 is longitudinal (z-axis direction).

The magnetization direction of the reference layer 302 may be identified using the Lorentz transmission electron microscope (LTEM), the magneto-optical Kerr effect microscope (MOKE), the spin-polarized scanning tunneling microscope (SP-STM), the magnetic force microscope (MFM), or the spin-polarized low-energy electron microscope (SPLEEM).

For the magnetoresistive element 300 to be the vortex-type TMR element, the free layer 306 needs to have the columnar structure extending in the z-axis direction and spreading in a planar direction intersecting the z-axis direction. In a cross section, as the height t of the free layer 306 in the z-axis direction and the effective size d of the free layer 306 in a planar direction, the height t is 4 nm or more, and the effective size d is not less than a value (2.57×10⁻²/Ms) obtained by dividing 2.57×10⁻² [A] by the saturation magnetization Ms [A/nm] of the free layer 306.

As illustrated in FIG. 1, in order to be a coreless vortex-type TMR element including a free layer 206 having an annular structure, the coreless vortex-type TMR element has a cross section in which the effective size d of the inner diameter of the annular structure is not less than a value (2.57×10⁻²/Ms) obtained by dividing 2.57×10⁻² [A] by the saturation magnetization Ms [A/nm] of the free layer 206.

The above effective size d is represented by d=2√ (S/π), where S is the cross-sectional area of the free layer, and π is pi.

As described above, according to the current sensor 10 having the longitudinal magnetic field type magnetic sensor according to each embodiment, components of the magnetic field in the x-axis direction and the y-axis direction can be suppressed, and a decrease in magnetic field detection accuracy can be suppressed.

Although the embodiments have been described above, the technical scope of the present invention is not limited to the scope described in the above embodiments. It is apparent to persons skilled in the art that various alterations or improvements can be added to the above-described embodiments. It is also apparent from the scope of the claims that the embodiments to which such alterations or improvements are added can be included in the technical scope of the invention.

The operations, procedures, steps, and stages of each process performed by an apparatus, system, program, and method shown in the claims, embodiments, or diagrams can be performed in any order as long as the order is not indicated by "prior to," "before," or the like and as long as the output from a previous process is not used in a later process. Even if the process flow is described using phrases such as "first" or "next" in the claims, embodiments, or diagrams, it does not necessarily mean that the process must be performed in this order.

### EXPLANATION OF REFERENCES

10 current sensor
20 magnetoelectric conversion element
22 magnetic sensing surface
30, 120 wire
34 bump
40 insulating sheet
100 signal processing IC
101 substrate
102 n-type deep well
103 p-type well
104 n-type source
105 n-type drain
106 gate insulating film
107 gate electrode
108a, 108b, 108c, 108d, 108e via
109 interlayer insulating film
130 sealing portion
140 conductor
144 turn portion
150 signal terminal
200, 300 magnetoresistive element
202, 302 reference layer
204, 304 insulating layer
206, 306 free layer.

What is claimed is:

1. A current sensor comprising:
a conductor having a first terminal portion extending in a first direction, a second terminal portion spaced apart from the first terminal portion in a second direction intersecting the first direction and extending in the first direction, a turn portion spaced apart from the first terminal portion and the second terminal portion in the first direction, a first body portion connected to the turn portion and the first terminal portion, and a second body portion spaced apart from the first body portion in the second direction and connected to the turn portion and the second terminal portion; and
a magnetoelectric conversion element that is arranged so as to be partially surrounded by the first body portion, the turn portion, and the second body portion in a plan view and that detects a magnetic field generated by a current flowing through the conductor, wherein
the first body portion has a first flow path portion connected to the turn portion, and a first enlarged portion connected to the first flow path portion and the first terminal portion, having a width larger than a width of the first flow path portion in the second direction, and protruding toward the second body portion,
the second body portion has a second flow path portion connected to the turn portion, and a second enlarged portion connected to the second flow path portion and the second terminal portion, having a width larger than a width of the second flow path portion in the second direction, and protruding toward the first body portion,
the magnetoelectric conversion element is located, in a plan view, between the first flow path portion and the second flow path portion and at a position overlapping a center line that is equidistant from a side of the first flow path portion facing the second flow path portion and a side of the second flow path portion facing the first flow path portion, and
each of a distance between a centroid of the magnetoelectric conversion element and the side of the first flow path portion and a distance between the centroid of the magnetoelectric conversion element and the side of the second flow path portion is smaller, in a plan view, than a distance between the centroid of the magnetoelectric conversion element and a side of the turn portion facing the magnetoelectric conversion element.

2. The current sensor according to claim 1, wherein a cross-sectional area of the turn portion is larger than a cross-sectional area of each of the first flow path portion and the second flow path portion.

3. The current sensor according to claim 1, wherein, in a side view, a magnetic sensing surface of the magnetoelectric conversion element and the conductor overlap each other.

4. The current sensor according to claim 2, wherein, in a side view, a magnetic sensing surface of the magnetoelectric conversion element and the conductor overlap each other.

5. The current sensor according to claim 1, further comprising:
an insulating layer arranged between the magnetoelectric conversion element and the conductor, wherein
the magnetoelectric conversion element is arranged such that a magnetic sensing surface of the magnetoelectric conversion element faces the insulating layer.

6. The current sensor according to claim 2, further comprising:
an insulating layer arranged between the magnetoelectric conversion element and the conductor, wherein
the magnetoelectric conversion element is arranged such that a magnetic sensing surface of the magnetoelectric conversion element faces the insulating layer.

7. The current sensor according to claim 1, wherein the magnetoelectric conversion element is a tunnel magnetoresistive element or a giant magnetoresistive element.

8. The current sensor according to claim 2, wherein the magnetoelectric conversion element is a tunnel magnetoresistive element or a giant magnetoresistive element.

9. The current sensor according to claim 7, wherein
the tunnel magnetoresistive element or the giant magnetoresistive element has a stacked structure including a reference layer, an insulating layer arranged above a first surface of the reference layer, and a free layer arranged above a first surface of the insulating layer on an opposite side from a second surface of the insulating layer facing the reference layer, and
a magnetization direction of the reference layer exists in a third direction intersecting the first direction and the second direction and along a stacking direction of the stacked structure.

10. The current sensor according to claim 8, wherein the tunnel magnetoresistive element or the giant magnetoresistive element has a stacked structure including a reference layer, an insulating layer arranged above a first surface of the reference layer, and a free layer arranged above a first surface of the insulating layer on an opposite side from a second surface of the insulating layer facing the reference layer, and
a magnetization direction of the reference layer exists in a third direction intersecting the first direction and the second direction and along a stacking direction of the stacked structure.

11. The current sensor according to claim 7, wherein the tunnel magnetoresistive element or the giant magnetoresistive element includes a free layer, and
the free layer has a columnar structure extending in a third direction intersecting a layer of the free layer and spreading in a planar direction intersecting the third direction, and has a cross section in which, for a height t of the free layer in the third direction and an effective size d of the free layer in the planar direction, the height t is 4 nm or more and the effective size d is not less than a value obtained by dividing 2.57×10⁻² [A] by a saturation magnetization Ms [A/nm] of the free layer.

12. The current sensor according to claim 8, wherein
the tunnel magnetoresistive element or the giant magnetoresistive element includes a free layer, and
the free layer has a columnar structure extending in a third direction intersecting a layer of the free layer and spreading in a planar direction intersecting the third direction, and has a cross section in which, for a height t of the free layer in the third direction and an effective size d of the free layer in the planar direction, the height t is 4 nm or more and the effective size d is not less than a value obtained by dividing 2.57×10⁻² [A] by a saturation magnetization Ms [A/nm] of the free layer.

13. The current sensor according to claim 7, wherein
the tunnel magnetoresistive element or the giant magnetoresistive element includes a free layer,
at least a part of at least the free layer has an annular structure extending in a third direction intersecting a layer of the free layer, and
the free layer has a cross section in which an effective size d of an inner diameter of the annular structure is not less than a value obtained by dividing 2.57×10⁻² [A] by a saturation magnetization Ms [A/nm] of the free layer.

14. The current sensor according to claim 1, further comprising:
a signal processing IC that processes a signal output from the magnetoelectric conversion element, wherein
the conductor is arranged to face a second surface of the signal processing IC, and
the magnetoelectric conversion element is arranged to face a first surface of the signal processing IC on an opposite side from the second surface.

15. The current sensor according to claim 14, further comprising:
a plurality of wires electrically connecting pads of the magnetoelectric conversion element and pads of the signal processing IC, wherein
in a plan view, a first pad of the magnetoelectric conversion element and a second pad of the signal processing IC that are connected to one wire of two wires among the plurality of wires, and a fourth pad of the magnetoelectric conversion element and a third pad of the signal processing IC that are connected to another wire of the two wires, are arranged on a straight line, or
a first line segment connecting the first pad and the fourth pad and a second line segment connecting the second pad and the third pad are in skew positions to each other in a plan view, and the first line segment and the second line segment have an intersection point in a plan view, and an area in a plan view of a first triangle having, as vertices, the intersection point, the first pad, and the second pad and an area in a plan view of a second triangle having, as vertices, the intersection point, the third pad, and the fourth pad are equal to each other.

16. The current sensor according to claim 15, wherein the signal processing IC has a pad connected to ground.

17. The current sensor according to claim 16, wherein
the signal processing IC has an impurity region electrically connected to the pad connected to ground and having a potential fixed to ground, and
at least a part of each of the plurality of wires overlaps the impurity region in a plan view.

18. The current sensor according to claim 14, wherein
the magnetoelectric conversion element has a magnetic sensing surface on a first surface on an opposite side from a second surface facing the first surface of the signal processing IC, and
the magnetoelectric conversion element and the signal processing IC are electrically connected via a via penetrating through the magnetoelectric conversion element in a direction from the first surface of the magnetoelectric conversion element toward the second surface.

19. The current sensor according to claim 14, wherein
the magnetoelectric conversion element has a magnetic sensing surface on a second surface facing the first surface of the signal processing IC, and
a pad provided on the second surface of the magnetoelectric conversion element and a pad provided on the first surface of the signal processing IC are electrically connected via a bump.

20. A current sensor comprising:
a conductor having a first terminal portion extending in a first direction, a second terminal portion spaced apart from the first terminal portion in a second direction intersecting the first direction and extending in the first direction, a turn portion spaced apart from the first terminal portion and the second terminal portion in the first direction, a first body portion connected to the turn portion and the first terminal portion, and a second body portion spaced apart from the first body portion in the second direction and connected to the turn portion and the second terminal portion; and
a magnetoelectric conversion element that is arranged so as to be partially surrounded by the first body portion, the turn portion, and the second body portion in a plan view and that detects a magnetic field generated by a current flowing through the conductor, wherein
the first body portion has a first flow path portion connected to the turn portion, and a first enlarged portion connected to the first flow path portion and the first terminal portion, having a width larger than a width of the first flow path portion in the second direction, and protruding toward the second body portion,
the second body portion has a second flow path portion connected to the turn portion, and a second enlarged portion connected to the second flow path portion and the second terminal portion, having a width larger than a width of the second flow path portion in the second direction, and protruding toward the first body portion, and
a cross-sectional area of the turn portion is larger than a cross-sectional area of each of the first flow path portion and the second flow path portion.
